(19) United States
(12) Patent Application Publication
(10) Pub. No.: US 2005/0173807 A1
(43) Pub. Date: Aug. 11, 2005

(54) High density vertically stacked semiconductor device

(76) Inventors: Jianbai Zhu, Plano, TX (US); Ray D. Harrison, Garland, TX (US)

Correspondence Address: TEXAS INSTRUMENTS INCORPORATED, P O BOX 655474, M/S 3999, DALLAS, TX, 75265, US

(21) Appl. No.: 10/772,709

(22) Filed: Feb. 5, 2004

(51) Int. Cl. H01L 23/48

(52) U.S. Cl. 257/777

(57) ABSTRACT

A high density, high speed semiconductor module including a plurality of active semiconductor chip pairs bonded face-to-face. A functional system within the footprint of a single-chip package is provided by vertically stacking flip-chip pairs and interconnecting the chip pairs on a substrate or package. Assembly of the device including various combinations of more than one chip pair, in combination with individual chips, advantageously utilizes known manufacturing technology and equipment.

### FIELD OF THE INVENTION

This invention relates to a vertically stacked multi-chip semiconductor circuit module; and more particularly to a high density flip-chip assembly.

### BACKGROUND OF THE INVENTION

In the ongoing search for higher levels of circuit integration to support system level requirements, many avenues have been explored. In particular, chip feature sizes have been substantially decreased, wafer processing technologies have been altered to allow different types of circuits on the same chip, and package-sizes and foot-prints have been minimized. Each approach is limited by state-of-the-art technology and cost constraints, both by the device manufacturer and the user. Wafer fabrication processes which have been optimized for one device technology, such as memory chips, may not be optimum for a different technology, and in fact it may be prohibitively costly to adapt an alternate process.

Another approach for integration of functions and reducing device size which supports more compact, higher performance systems is the assembly of multiple chips into a single package. Multiple chips of the same or different device technologies are included in a single package or on an interconnecting substrate which provides contacts to the next level of interconnection.

As illustrated in FIG. 1, multiple electronic devices 11 and 12 are assembled and interconnected horizontally on a common substrate 13. The combination may provide a functional system or subsystem referred to as a multi-chip module 10. The substrate 13 may support integrated circuits 11, discrete components 12, buried ground planes (not shown), or other structures which enhance device and/or system performance.

Integration of multiple chips in the same package has been developed both in the horizontal and vertical planes. Historically, vertical integration has been favored by memory circuits which provide a device 20 having a larger memory capacity within the same footprint as a single device, as shown in FIG. 2. A number of similar devices 21 of relatively low pin-count are stacked atop each other and are interconnected by interposers 23 to each other and to external contacts 22.

Yet another device 30 which makes use of more advanced technology includes active silicon chips 31 in a vertical stack with separators 34 between each of the active devices 31. The active chips 31 are interconnected at the substrate 33 level, as shown in FIG. 3a. Typically each of these vertically integrated chips 31 is separated from each successive chip by an insulating material 34 which electrically isolates the devices and mechanical protects the active surfaces.

Materials which have been used for separation between vertically stacked chips include laminate materials, polymeric films, adhesives, or in some cases bare silicon chips. The use of silicon chips as separators between active chips offers some significant advantages over other materials, namely in providing rigidity to the device, in having the same coefficient of thermal expansion as the active chips, and in providing good thermal conduction to help spread and dissipate heat from the device. One of the disadvantages of silicon spacer chips is in increasing the package height without adding functionality.

In FIG. 3b the active faces of chips 35 and 36 are stacked face-to-face, and are connected to each other by flip-chip technology. The face-to-face interconnected device 301 is typically referred to as “chip-on-chip”, and the connections between the chips are made by conductive solder bumps 37. The supporting base chip 35 is larger than upper chip 36 and has connections to substrate 38.

Yet another known device is illustrated in FIG. 3c, having vertically stacked chips including a first chip 331 with flip-chip bonds 330 to a substrate 335 and a second chip 332 glued to the back side of the first chip 331. A third chip 333 has flip-chip connections to the second chip 332. One chip in the flip-chip pair is electrically connected to the substrate either by wire bonds to the upward-facing chip (not shown) or a vertical interconnect 336 to the downward-facing top chip 333. Flip-chip bonds 330 between substrate 335 and first chip 331 in the stack are subject to thermally induced stresses due to the mismatch in thermal expansion, which causes reduced reliability.

It is well known that as brittle silicon chip sizes have increased, and the chips are adhered to different substrate materials, thermal and mechanical stresses have resulted in yield losses and reliability failures. Not only can the stresses be a concern for mechanical distortion and cracking of chips and interconnections, or interconnection interfaces, but in high speed devices response times may be altered, thereby interfering with device performance. Materials having similar coefficients of expansion help mitigate these stresses.

A reliable, small footprint, high density assembly of semiconductor chips which integrates system functions within a device is an important goal, and a cost effective assembly of such a device wherein existing technologies and equipment are utilized would be welcome.

### SUMMARY OF THE INVENTION

In accordance with an embodiment of the invention, a multi-chip semiconductor module is provided that includes a vertical stack of active semiconductor chip pairs connected face-to-face and mounted on an interconnecting substrate to form a functional system within the footprint of a single package. The fully functional chips vertically stacked within the footprint of a single package offer advantages both in device density, and in increased operating speed between closely spaced interacting chips.

In another embodiment, the vertical chip stack includes a combination of two or more flip-chip pairs, in addition to one or more single chips. The chip pairs are made up of two integrated circuit chips assembled with active face-to-face interconnections, and contacts to the substrate. One or more single integrated circuit chips or other electronic devices complete the vertical stack and are connected directly to the substrate. Conductors on the substrate provide interconnections between the chip pairs in the stack and to single chips within the device.

Chip pairs preferably include, but are not limited to a processor chip coupled to a memory device, such as RAM, flash, or buffer storage chip. Performance of the device pair is enhanced by very short, low inductance interconnections between chips in the pairs and to other chips in the assembly. Other chips within the device stack provide additional system functions to form an electronic system or subsystem. An example of such a system level device is a video chip pair, an audio chip pair, and a controller device, as could be used in a television set.

The chip pairs are interconnected by flip-chip contacts, such as conductive bumps or anisotropic conductive materials. Contact may be made directly between facing chip terminals, or connections may be rerouted on either or both chip surfaces. A polymeric underfill material may be placed between the flipped chips to avoid stress damage to the contacts.

The inactive surface of the first chip in the stack is adhered to the substrate and inactive surfaces of subsequent chips in the stack are adhered to the successive chip pair or individual chip by a polymeric adhesive.

The larger upward facing chip in each flip-chip pair, and the single chip(s) are connected to bonding lands on the substrate by wire bonds, TAB bonds, or other flexible interconnection techniques. Patterned interconnections on the substrate provide connectivity between the various chip pairs and single chips.

In another embodiment, the stacked chip semiconductor device is housed in a BGA (ball grid array) package having external solder bump contacts, a substrate with patterned interconnections, and a protective body. The body of such a package may be molded in a thermosetting polymer or may include a cap filled with a protective polymer.

The semiconductor device of this invention includes many configuration options. The number of chips in the vertical stack is determined by functional requirements and system constraints, and by the assembly technology.

For a more complete understanding of the invention and advantages thereof, reference is made to the following description and accompanying drawings.

### BRIEF DESCRIPTION OF THE DRAWINGS

FIG. 1 schematically illustrates an arrangement of components in a known multi-chip module.

FIG. 2 is a vertically stacked device of known art.

FIG. 3a depicts a vertically stacked chip set with inactive separators of known art.

FIG. 3b is a chip-on-chip device of prior art.

FIG. 3c is another known assembly, including a first chip bonded to a substrate, and a flip-chip pair glued to the backside of the first chip.

FIG. 4 is a high density vertical chip assembly of the invention, including two flip-chip pairs and an individual chip.

FIG. 5 is a vertical chip assembly comprising two face-to-face chip pairs.

FIG. 6a is a vertical chip assembly including two flip-chip pairs and at least two electronic components wire bonded to a substrate.

FIG. 6b is a vertical chip assembly including two face-to-face chip pairs and at least two electronic components flip chip connected to a third chip.

FIGS. 7a and 7b schematically depict a high density device for an audio-video system and the communication links.

FIG. 8 illustrates a vertical chip assembly having wire and TAB bonds to the substrate.

FIG. 9 is a multi-tier BGA package with a vertically stacked chip set.

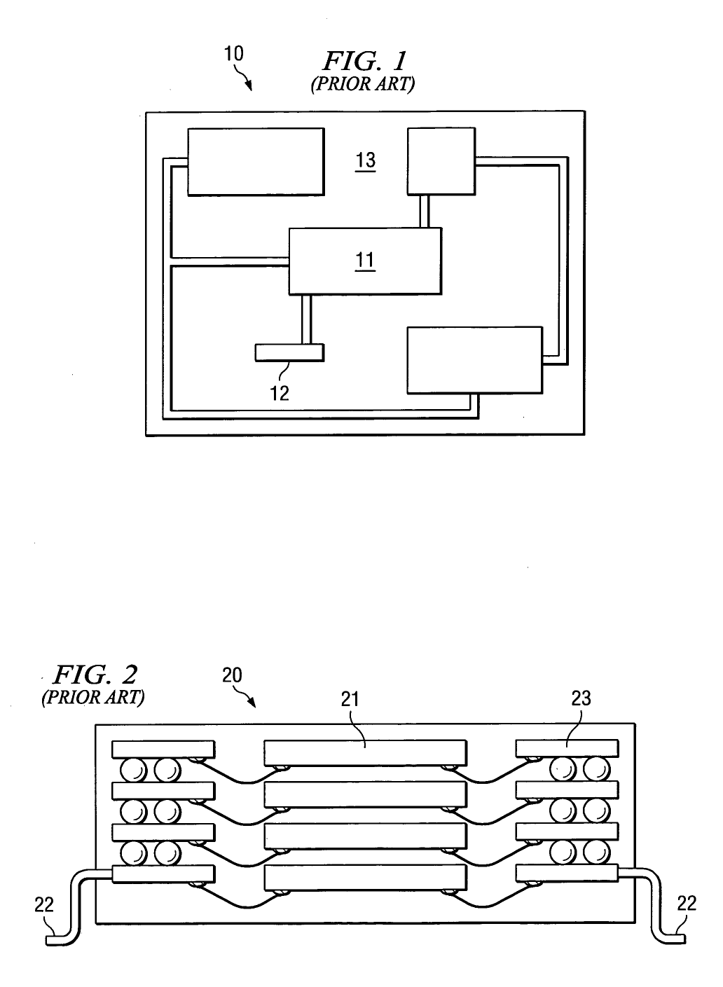

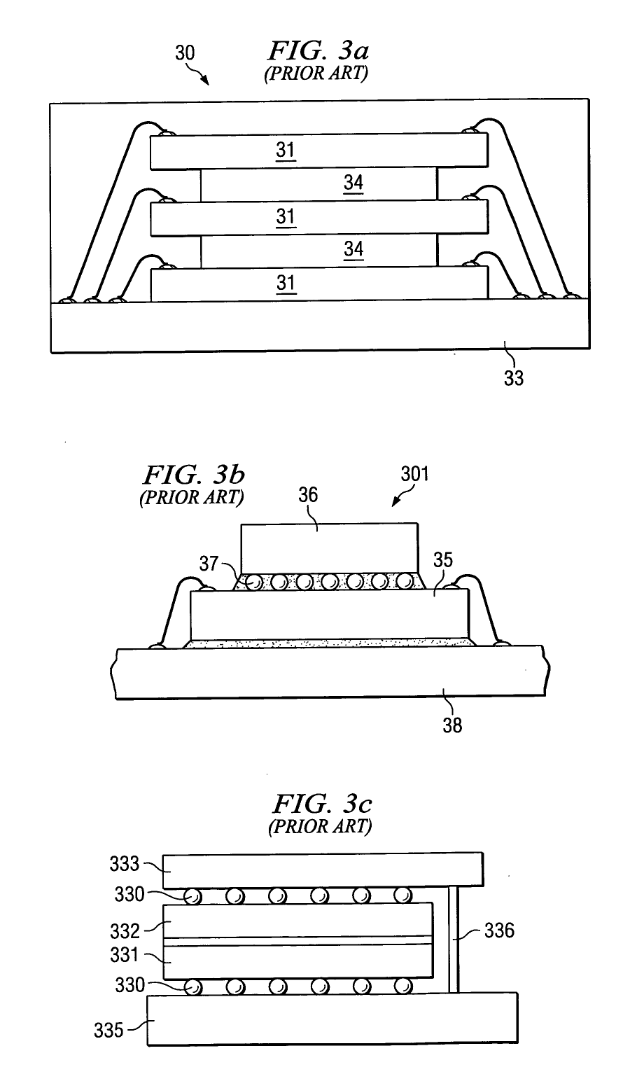

### DETAILED DESCRIPTION OF THE DRAWINGS

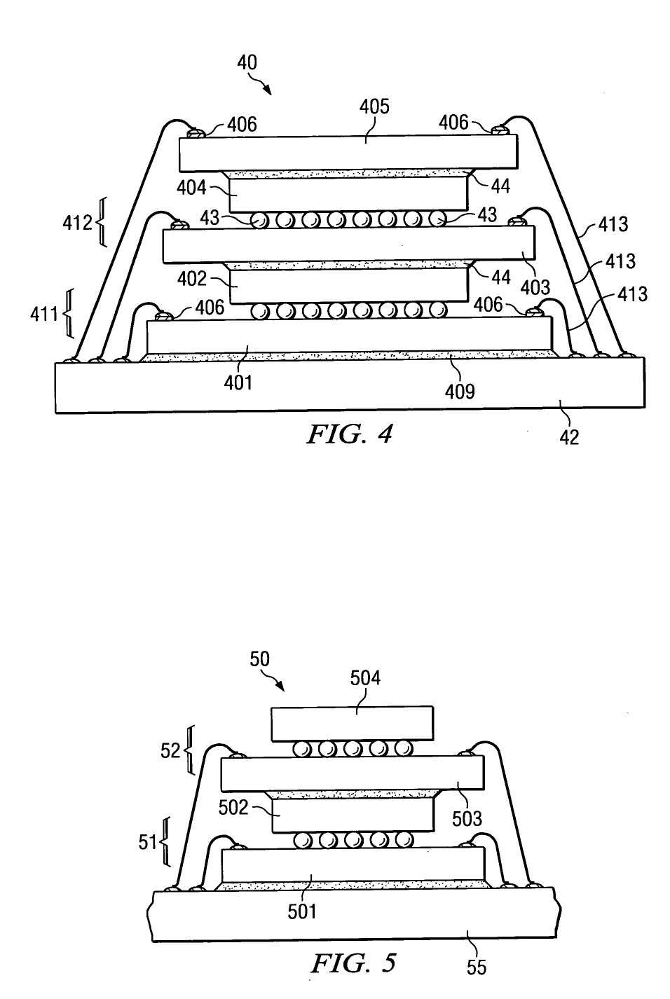

FIG. 4 provides a cross sectional view of one embodiment of the invention, a high density semiconductor device 40 including two pairs of semiconductor chips 411 and 412 face-to-face interconnected by flip-chip technology. Each of the chips in the assembly is a functional device, such as an integrated circuit, and each chip has an active and an inactive surface. The active surfaces are patterned with conductors and dielectric materials to form functional semiconductor devices, and the inactive surfaces are the unpatterned backsides of the chips. Each chip pair 411,412 includes a base or bottom chip 401,403 having the active surface facing upward, a downward facing top chip 402,404, and a plurality of flip-chip bonds 43 connecting the active chip surfaces. The base chip 401,403 is larger in area than the top chip 402,404 and includes a plurality of exposed bond pads 406.

In the embodiment illustrated in FIG. 4, the inactive surface of the first chip 401 is adhered to a substrate 42 by a polymeric adhesive 409, and the exposed bond pads 406 on the active surface are interconnected to bonding lands on the substrate 42 by wire bonds 413. The active surface of the second chip 402 is interconnected to the active surface of the first chip 401 by conductive bumps 43, preferably comprising solder, and forms the first flip-chip pair 411.

The inactive surface of the third chip 403 is adhered to the inactive surface of the second chip 402 by a polymeric material 44. Similarly, the fourth chip 404 is face-to-face flip-chip connected to the active surface of the third chip 403, thereby providing a second chip pair 412 in the stack. Wires 413 bonded to pads 406 near the edges of the third chip 403 connect chip pair 412 to substrate 42.

The inactive surface of an individual fifth chip 405 is adhered to the inactive surface of the forth chip 404, and bond pads 406 on the active, upward facing surface of chip 405 are connected to the substrate by wires 413.

The embodiment of FIG. 4 comprises two chip pairs 411,412, an individual chip 405, a plurality of flip-chip contacts 43, and an interconnecting substrate 42.

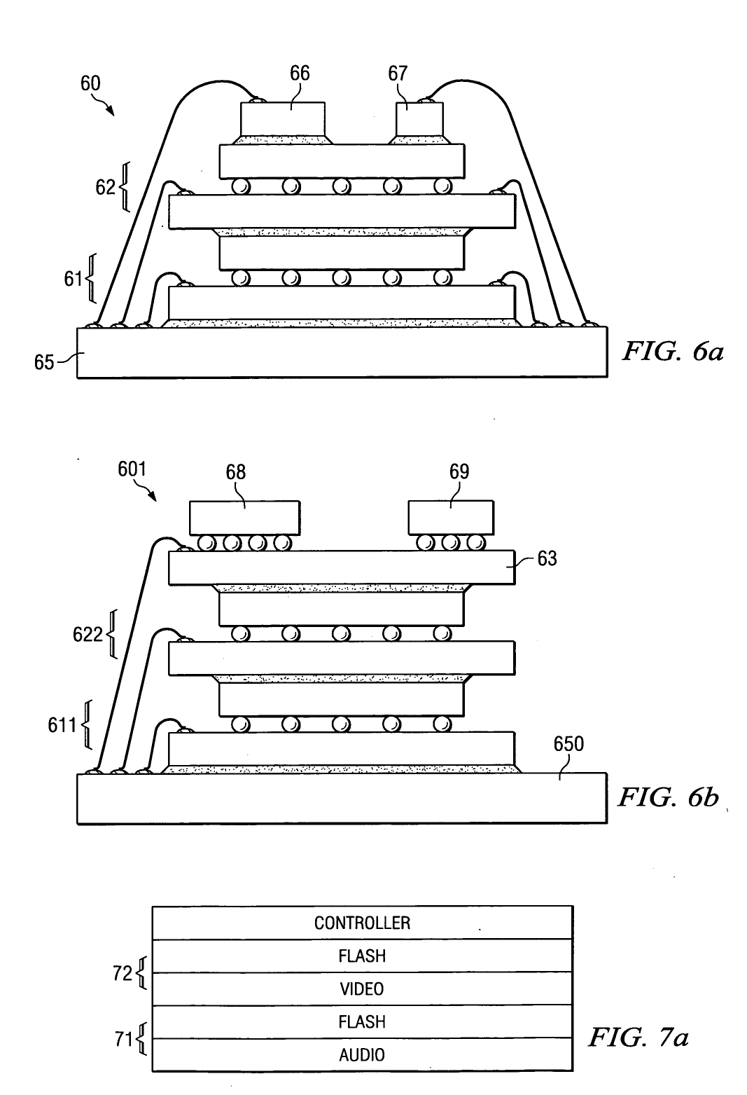

Various embodiments of the invention include different configurations of vertically stacked chips and chip pairs. In the embodiment of FIG. 5, the assembled device 50 includes only flip-chip pairs 51 and 52. In each chip pair, the smaller chip 502,504 is positioned atop a larger area chip 501,503 and the larger chips 501,503 are interconnected to a substrate 55. Two or more chip pairs are included in this embodiment. The number of chip pairs in a device is determined by system requirements, and by device height and interconnection technology constraints. In FIG. 6a, vertical chip assembly 60 includes two flip-chip circuit pairs 61 and 62 mounted on substrate 65. Components 64 and 66 are mounted on top of flip-chip pair 62 and interconnected to substrate 65 by wire bonds. Alternately, multiple individual components 68, 69 atop a vertical chip stack 601 are flip-chip mounted to a supporting chip 63 as shown in FIG. 6b. The supporting chip 63 is adhered to the backside of chip pair 622. Another flip-chip pair 611, supporting pair 622, is mounted on substrate 650. Wire bonds connect chip 63 and pairs 611 and 622 to substrate 650.

FIGS. 4, 5 and 6 have illustrated some potential configurations of a high density vertical chip assembly including more than one flip-chip pair, or one or more flip chip pairs combined with one or more individual chips. However, the invention is not limited to these specific combinations, but instead these drawings show some variations of the invention and that multiple configurations are within the spirit of the invention.

It will be recognized that some integrated circuits will be configured with flip chip contacts which mate directly to contact pads on the adjoining chip, but in the majority of cases, connection sites will be rerouted on the larger chip to mate with conductive contacts on the smaller chip. Rerouting of bond sites by patterned conductors on a dielectric film is known in the industry.

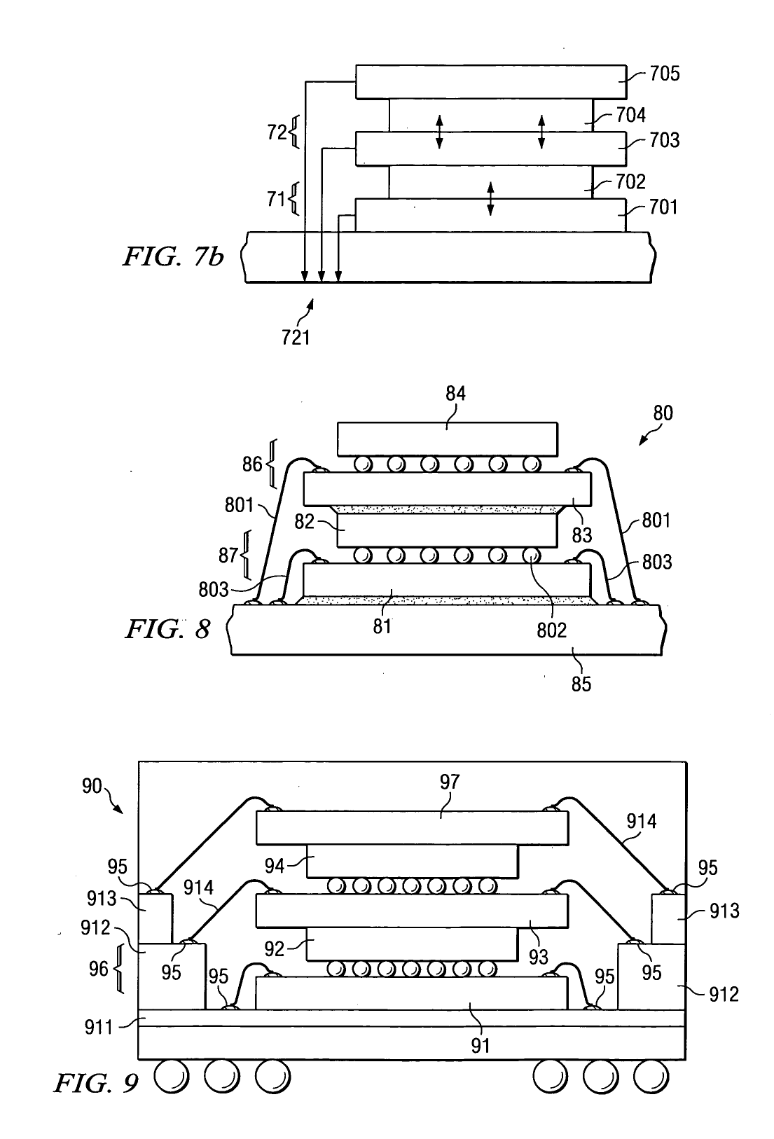

An exemplary device, illustrated schematically in FIGS. 7a and 7b, provides the necessary components for system having both audio and video functions. The integrated circuits include an audio chip 701 directly connected to a flash memory unit 702, thereby enhancing response time between the chips. A video device 703 is similarly interconnected with a flash memory chip 704 to provide another rapid response chip pair 72. A system controller device 705 is included in the stack, and together with the chip pairs 71 and 72, the integrated circuits provide the major components of an audio/video system within the footprint of a single device.

Arrows in FIG. 7b illustrate communication links within the device; direct connection between components 701,702 and 703,704 of the chip pairs 71 and 72, between the chip pairs 71,72 and the substrate 75, between chip 705 and the substrate 75. Multiple arrows 721 schematically illustrate that all components are interconnected on the substrate 75, i.e., communications may occur between the individual controller chip 705 and each of the chip pairs 71 and 72 by way of conductors on the substrate 75.

Connections between the substrates and base chips illustrated in FIGS. 4, 5, and 6 have been made by wire bonds 403,503,603. In an alternate embodiment, TAB (tape automated bonding) is the preferred interconnection for some or all of the upward facing chips which contact the substrate.

In FIG. 8, the first chip 81 in the stack includes bond wires 803 to the substrate 85, and the second chip 82 is flip-chip bonded by bumps 802 to the first chip to form chip pair 87. A second chip pair 86 may be preassembled with flip-chip 84 on chip 83, and TAB tape 801 connected to the active surface of the third chip 83 prior to assembly into the device 80. The preassembled chip pair is aligned, the inactive surface of the third chip 83 is adhered to the inactive surface of the second chip 82, and the TAB tape is bonded to the substrate. TAB or other connectors having patterned metal conductors on a flexible insulating film provide contacts on the base chip prior to assembly onto the preceding chip set, and thereby facilitate ease of assembly to the substrate for multi-component devices. In the example in FIG. 8, the fourth chip 84 could be flip chip assembled to the third chip either before or after adhering the third chip to the device stack. Alternately, both chip pairs 86 and 87 could be TAB bonded and/or be preassembled.

Substrates 42, 55, 65, 72 and 85 of the previous embodiments have been depicted as planar surfaces. The planar surfaces represent multiple layers of patterned interconnections and dielectrics typically found in either a BGA package surface or the surface of a printed wiring board. The package may be constructed as a cavity or an overmolded device. The vertical assembly of chips is adhered and interconnected directly to the substrate.

The substrate of a preferred high density vertical chip embodiment is a multilayer ball grid array (BGA) package 90 having bonding lands 95 on different tiers 911,912,913, as illustrated in FIG. 9. Tiered bonding levels facilitate ease of assembly, in particular for wire bonded embodiments wherein each chip pair 96 or individual chip 97 is interconnected sequentially to the substrate. In the assembly process, the first chip 91 is wire bonded to the first substrate level 911 of the package, the second chip 92 is aligned to the active surface of the first chip 91 and flip chip bonded. The third chip 93 is adhered to the inactive surface of the second chip 92 and bond wires 914 are connected to the package second tier 912 prior to flip chip bonding the fourth chip 94. A fifth chip 95 is adhered to the inactive surface of the fourth chip 94 and third set of bond wires 914.attached to the third tier 913.

It will be recognized that the exact configuration and assembly method of a high density vertical semiconductor chip assembly may take different forms, and that modifications will become apparent to those skilled in the art. Therefore, it is intended that the appended claims be interpreted as broadly as possible.

1- A semiconductor device comprising:
a plurality of semiconductor chips having an active and an inactive surface in a vertical stack;
said chips including at least two flip-chip pairs having their active surfaces bonded face-to-face;
a substrate having a plurality of bond pads and interconnection circuitry, and
a plurality of conductive connections between said chips and said substrate.

2- The device of claim 1 wherein said flip-chip pairs comprise a base chip with said active surface facing upward and having exposed bond pads, a chip with said active surface facing downward, and a plurality of conductive flip-chip bonds interconnecting said active surfaces.

3- The device of claim 1 wherein the inactive surfaces of said chips are adhered to said substrate or to the inactive surface of a successive chip pair by a polymeric adhesive.

4- The device of claim 1 wherein each of said chips having an upward facing active surface is connected to bond pads on said substrate.

5- The device of claim 1 wherein one chip in a chip pair includes a memory circuit, such as RAM, flash or buffer storage unit.

6- The device of claim 2 wherein said interconnection by flip-chip bonds includes solder bumps.

7- The device of claim 2 wherein said interconnection by flip-chip bonds includes an anisotropic conductive material.

8- The device of claim 1 wherein patterned circuitry on said substrate includes interconnections between each of said chips connected to the substrate.

9- The device of claim 1 wherein said plurality of semiconductor chips coupled with said substrate comprises a functional electronic system.

10- The device of claim 2 wherein said connections between said chips and substrate comprise wire bonds.

11- The device of claim 2 wherein said connections between said chips and substrate comprise TAB bonds.

12- The device of claim 2 wherein said flip-chip bonds interconnecting said chip pairs includes rerouting of conductors on the active surface of one or both chips.

13- The device of claim 1 wherein said semiconductor chips include a video chip, an audio chip, a controller chip, and two or more flash memory chips.

14- The device of claim 2 wherein the area between conductive bonds includes an underfill material.

15- The semiconductor device of claim 1 wherein said substrate is a BGA package substrate.

16- A semiconductor device comprising:
a multilayer BGA package having a plurality of bond pads and interconnection circuitry, a plurality of semiconductor chip pairs connected face-to-face in a vertical stack, wherein each of said chips has an active and an inactive surface, and a plurality of connections between said chips and package bond pads.

17- The device of claim 16 wherein said BGA package includes multiple layers of conductors and bonding lands on different tiers.

18- The device of claim 16 wherein said package includes contacts to a second level of interconnection.

19- A process for assembling a vertically stacked semiconductor device including more than one flip chip pairs comprising the following steps:
providing a substrate having a plurality of bond pads and interconnections between said pads,
attaching the inactive surface of the first chip to said substrate by a polymeric material,
aligning the active surface of the second chip to the active surface of the first chip and bonding the active surfaces by flip chip bonds to form a chip pair,
interconnecting exposed bond pads of the first chip to the substrate bond pads,
adhering the inactive surface of the third chip to the inactive surface of the second chip,
aligning the active surface of the fourth chip to the active surface of the third chip and bonding the active surfaces by flip chip bonds to form a second chip pair, and
connecting exposed bond pads of the third chip to the substrate bond pads.

20- The process of claim 19 wherein said flip chip pairs are preassembled by aligning and flip chip bonding prior to positioning in said chip stack.
